(19) United States
(12) Patent Application Publication
(10) Pub. No.: US 2024/0347574 A1
(43) Pub. Date: Oct. 17, 2024

(54) DEVICE, SYSTEM, AND MOVING BODY

(71) Applicant: CANON KABUSHIKI KAISHA, Tokyo (JP)

(72) Inventor: DAIKI SHIRAHIGE, Kanagawa (JP)

(21) Appl. No.: 18/633,238

(22) Filed: Apr. 11, 2024

(30) Foreign Application Priority Data
Apr. 17, 2023 (JP) 2023-067177

(51) Int. Cl. H01L 27/146

(52) U.S. Cl. CPC H01L 27/14636; H01L 27/14607; H01L 27/14627; H01L 27/1463

(57) ABSTRACT

A device includes a plurality of photodiodes each including a first region of a first conductivity type and a second region of a second conductivity type, a microlens provided to be shared by at least a first photodiode and a second photodiode of the plurality of photodiodes, and a first contact configured to supply a first voltage to the first region, wherein a length in a first direction of the first region of the first photodiode is different from a length in a second direction of the first region of the first photodiode orthogonal to the first direction.

### BACKGROUND

### Technical Field

The aspect of the embodiments relates to a photoelectric conversion device, and a system and a moving body using the photoelectric conversion device.

### Description of the Related Art

A photoelectric conversion device that includes an avalanche photodiode (hereinafter, “APD”) has been known.

Japanese Patent Application Laid-Open No. 2020-141122 discusses a configuration which enables phase difference detection by arranging one microlens on a plurality of photoelectric conversion units including the APDs.

However, in Japanese Patent Application Laid-Open No. 2020-141122, a study is not sufficiently conducted with respect to an appropriate arrangement of APDs when a shape of a pixel is not a square.

### SUMMARY

According to an aspect of the embodiments, a device includes a plurality of photodiodes each including a first region of a first conductivity type and a second region of a second conductivity type, a microlens provided to be shared by at least a first photodiode and a second photodiode of the plurality of photodiodes, and a first contact configured to supply a first voltage to the first region, wherein a length in a first direction of the first region of the first photodiode is different from a length in a second direction of the first region of the first photodiode orthogonal to the first direction.

According to another aspect of the embodiments, a device includes a plurality of photodiodes each including a plurality of first regions of a first conductive type and a plurality of second regions of a second conductive type, a microlens provided to be shared by at least a first photodiode and a second photodiode of the plurality of photodiodes, and a plurality of first contacts configured to supply a first voltage to each of the plurality of first regions of the first photodiode, wherein, at least two first regions of the plurality of first regions of the first photodiode are arranged in a first direction, and wherein a number of first regions arranged in the first direction is greater than a number of first regions arranged in a second direction orthogonal to the first direction.

Further features of the disclosure will become apparent from the following description of exemplary embodiments with reference to the attached drawings.

### BRIEF DESCRIPTION OF THE DRAWINGS

FIG. 1 is a diagram illustrating a schematic view of an image capturing device.

FIG. 2 is a diagram illustrating a schematic view of a pixel array.

FIG. 3 is a block diagram of the image capturing device.

FIG. 4 is an equivalent circuit diagram of a pixel.

FIGS. 5A, 5B, and 5C are diagrams illustrating operation of a single-photon avalanche diode (SPAD) pixel.

FIG. 6 is a diagram illustrating a plan view of a pixel arranged on the image capturing device according to a first exemplary embodiment.

FIG. 7 is a diagram illustrating a cross-sectional view of the pixel arranged on the image capturing device according to the first exemplary embodiment.

FIG. 8 is a diagram illustrating a cross-sectional view of the pixel arranged on the image capturing device according to the first exemplary embodiment.

FIG. 9 is a diagram illustrating a cross-sectional view of the pixel arranged on the image capturing device according to the first exemplary embodiment.

FIG. 10 is a diagram illustrating a plan view of a pixel arranged on an image capturing device according to a second exemplary embodiment.

FIG. 11 is a diagram illustrating a cross-sectional view of the pixel arranged on the image capturing device according to the second exemplary embodiment.

FIG. 12 is a diagram illustrating a plan view of a pixel arranged on an image capturing device according to a third exemplary embodiment.

FIG. 13 is a diagram illustrating a cross-sectional view of the pixel arranged on the image capturing device according to the third exemplary embodiment.

FIG. 14 is a diagram illustrating a plan view of a pixel arranged on the image capturing device according to a fourth exemplary embodiment.

FIG. 15 is a functional block diagram of a photoelectric conversion system according to a fifth exemplary embodiment.

FIGS. 16A and 16B are functional block diagrams of a photoelectric conversion system according to a sixth exemplary embodiment.

FIG. 17 is a functional block diagram of a photoelectric conversion system according to a seventh exemplary embodiment.

FIG. 18 is a functional block diagram of a photoelectric conversion system according to an eighth exemplary embodiment.

FIGS. 19A and 19B are functional block diagrams of a photoelectric conversion system according to a ninth exemplary embodiment.

### DESCRIPTION OF THE EMBODIMENTS

Exemplary embodiments described hereinafter are merely examples embodying a technical sprit of the present disclosure, and not intended to limit the present disclosure. In each of the drawings, for the sake of clear descriptions, sizes and a positional relationship of members may be illustrated with exaggeration. In the following descriptions, a same reference numeral is applied to constituent elements similar to each other, and descriptions thereof may be omitted.

Hereinafter, the exemplary embodiments of the present disclosure are described in detail with reference to the appended drawings. In the following descriptions, terms describing a particular direction and positions, e.g., “up”, “down”, “right”, and “left” and other terms which include these terms are used as necessary. These terms are used for the sake of simplicity and easy understanding of the exemplary embodiments described with reference to the appended drawings, and meanings of these terms should not be construed as limiting the technical range of the present disclosure.

In the following descriptions, a signal is acquired from a cathode of an avalanche photodiode (APD), and electric potential of an anode thereof is fixed. Thus, a semiconductor region of a first conductive type which includes electric charges of polarity the same as the polarity of signal electric charges as majority carriers is an N-type semiconductor region, and a semiconductor region of a second conductive type which includes electric charges of polarity different from the polarity of the signal electric charges as the majority carriers is a P-type semiconductor region.

The present disclosure can also be realized in a case where the signal is acquired from the anode of the APD and the electric potential of the cathode thereof is fixed. In this case, the semiconductor region of the first conductive type which includes electric charges of the polarity the same as the polarity of the signal electric charges as the majority carriers is a P-type semiconductor region, and the semiconductor region of the second conductive type which includes electric charges of the polarity different from the polarity of the signal electric charges as the majority carriers is an N-type semiconductor region. Hereinafter, the present disclosure is described with respect to a case where the electric potential of one of the nodes of the APD is fixed. However, the electric potential of both of the nodes may be changed.

When a term “impurity concentration” is simply used in this specification, the term refers to a net impurity concentration acquired by subtracting a value compensated by impurities of a reverse conductive type. In other words, “impurity concentration” refers to a net doping concentration. A region where a P-type additive impurity concentration is higher than an N-type additive impurity concentration is the P-type semiconductor region. On the contrary, a region where an N-type additive impurity concentration is higher than a P-type additive impurity concentration is the N-type semiconductor region.

In this specification, “planar view” refers to a view seen from a direction perpendicular to a face on the opposite side of a light incident face of a semiconductor layer described below. Further, “cross section” refers to a face perpendicular to a face on the opposite side of the light incident face of the semiconductor layer. In a case where the light incident face of the semiconductor layer is a rough face in a microscopic view, the planar view is defined by using the light incident face of the semiconductor layer in a macroscopic view as a reference.

The below-described semiconductor layer 300 has a first face, and a second face on the opposite side of the first face and on which light is incident. In this specification, a depth direction is a direction heading toward the second face from the first face of the semiconductor layer 300 in which the APD is arranged. Hereinafter, the first face may be referred to as a “front face”, and the second face may be referred to as a “back face”. A direction heading toward the back face of the semiconductor layer 300 from a predetermined position in the semiconductor layer 300 may be expressed as a “deeper” direction. Further, a direction heading toward the front face of the semiconductor layer 300 from a predetermined position in the semiconductor layer 300 may be expressed as a “shallower” direction.

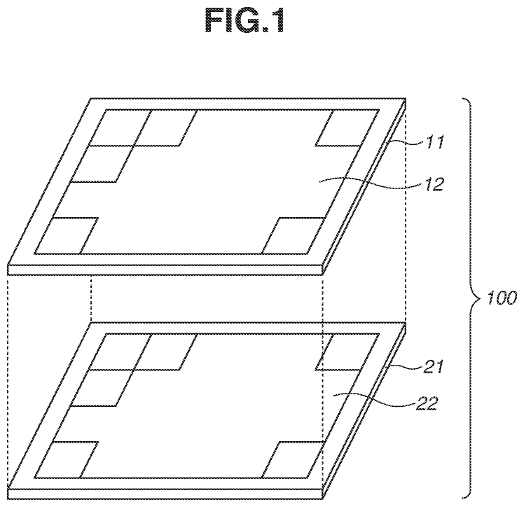

First, a configuration common to the following exemplary embodiments is described with reference to FIG. 1 to FIG. 5C.

FIG. 1 is a diagram illustrating a configuration of a laminated photoelectric conversion device 100. The photoelectric conversion device 100 includes two substrates, i.e., a sensor substrate 11 and a circuit substrate 21, laminated and electrically connected to each other. The sensor substrate 11 includes a first semiconductor layer (semiconductor layer 300) including a photoelectric conversion element 102 and a first wiring structure described below. The circuit substrate 21 includes a second semiconductor layer including a circuit for a signal processing unit 103 and the like, and a second wiring structure described below. The second semiconductor layer, the second wiring structure, the first wiring structure, and the first semiconductor layer are laminated in this order to constitute the photoelectric conversion device 100. The photoelectric conversion device 100 described in each of the exemplary embodiments is a backside illumination type photoelectric conversion device on which light is incident from a second face and a circuit board is arranged on a first face thereof.

Hereinafter, the sensor substrate 11 and the circuit substrate 21 in a form of diced chips are described. However, these substrates 11 and 21 do not have to be the chips. For example, the substrates 11 and 21 may be provided as wafers. The substrates 11 and 21 provided as wafers may be laminated together and then diced. Alternatively, the substrates 11 and 21 provided as wafers may be first cut into chips and then laminated and bonded together.

A pixel region 12 is arranged on the sensor substrate 11, and a circuit region 22 for processing a signal detected from the pixel region 12 is arranged on the circuit substrate 21.

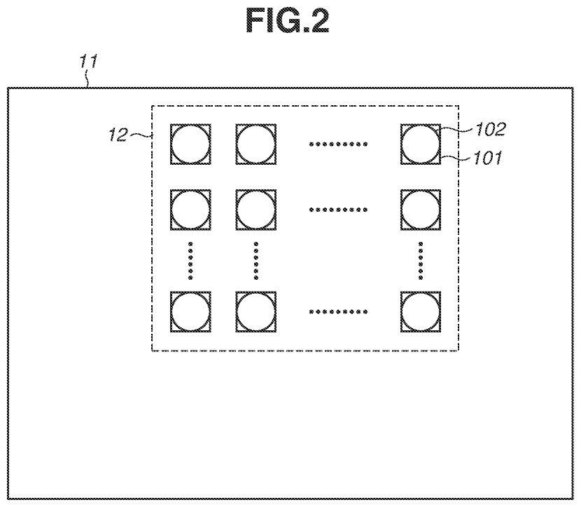

FIG. 2 is a diagram illustrating an arrangement example of the sensor substrate 11. Pixels 101, each of which includes a photoelectric conversion element 102 having an APD, are arranged in a two-dimensional array state and form a pixel region 12 in a planar view.

Typically, the pixels 101 are pixels for forming an image. However, an image does not always have to be formed in a case where the pixels 101 are used for implementing a time-of-flight (ToF) system. In other words, the pixels 101 may be used for measuring arrival time of light and a light amount.

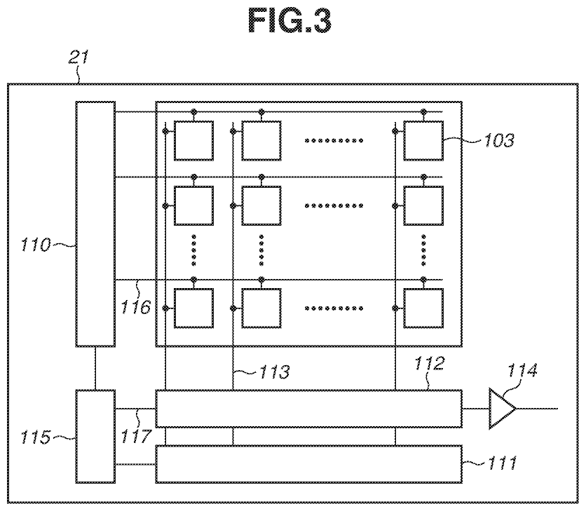

FIG. 3 is a block diagram illustrating a configuration of the circuit substrate 21. The circuit substrate 21 includes signal processing units 103 for processing electric charges photoelectrically converted by photoelectric conversion elements 102 illustrated in FIG. 2, a read-out circuit 112, a control pulse generation unit 115, a horizontal scanning circuit 111, a signal line 113, and a vertical scanning circuit 110.

Each of the photoelectric conversion elements 102 in FIG. 2 and each of the signal processing units 103 in FIG. 3 are electrically connected to each other via connection wiring arranged for each of the pixels 101.

The vertical scanning circuit 110 receives a control pulse supplied from the control pulse generation unit 115 and supplies the control pulse to each of the pixels 101. A logic circuit, such as a shift register or an address decoder, is used as the vertical scanning circuit 110.

A signal output from the photoelectric conversion element 102 arranged on the pixel 101 is processed by the signal processing unit 103. The signal processing unit 103 includes a counter and a memory, and a digital value is stored in the memory.

In order to read signals from the memory of each of the pixels 101 storing digital signals, the horizontal scanning circuit 111 inputs a control pulse for sequentially selecting each row to the signal processing units 103.

With respect to the selected row, a signal is output to the signal line 113 from a signal processing unit 103 of a pixel 101 selected by the vertical scanning circuit 110.

The signal output to the signal line 113 is output to a recording unit or a signal processing unit arranged on the outside of the photoelectric conversion device 100 via an output circuit 114.

In FIG. 2, photoelectric conversion elements 102 may be arranged in the pixel region 12 in a one-dimensional array state. A function of the signal processing unit 103 does not always have to be individually provided to all of the photoelectric conversion elements 102. For example, one signal processing unit 103 may be shared by a plurality of photoelectric conversion elements 102, and signal processing may sequentially be executed thereby.

As illustrated in FIGS. 2 and 3, the plurality of signal processing units 103 is arranged in a region overlapping with the pixel region 12 in a planar view. Then, the vertical scanning circuit 110, the horizontal scanning circuit 111, the read-out circuit 112, the output circuit 114, and the control pulse generation unit 115 are arranged to overlap with a region between an edge of the sensor substrate 11 and an edge of the pixel region 12 in a planar view. In other words, the sensor substrate 11 includes the pixel region 12 and a non-pixel region arranged to surround the pixel region 12. Then, the vertical scanning circuit 110, the horizontal scanning circuit 111, the read-out circuit 112, the output circuit 114, and the control pulse generation unit 115 are arranged in a region overlapping with the non-pixel region in a planar view.

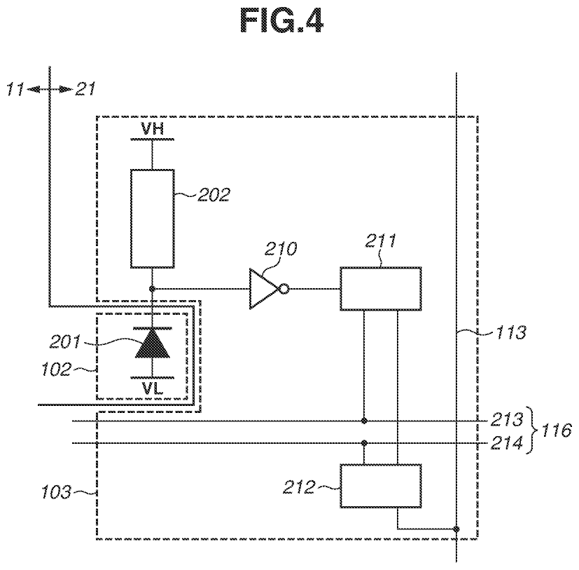

FIG. 4 is an example of a block diagram including an equivalent circuit of the circuit in FIGS. 2 and 3.

In FIG. 4, the photoelectric conversion element 102 including an avalanche photodiode (APD) 201 is arranged on the sensor substrate 11, and the other members are arranged on the circuit substrate 21.

The APD 201 generates an electric charge pair based on incident light by photoelectric conversion. A voltage VL (first voltage) is supplied to the anode of the APD 201. Further, a voltage VH (second voltage) higher than the voltage VL supplied to the anode is supplied to the cathode of the APD 201. A reverse bias voltage which causes the APD 201 to perform avalanche multiplication is supplied to each of the anode and the cathode thereof. By supplying the above-described voltage to the APD 201, avalanche multiplication occurs in the electric charges generated based on the incident light, so that an avalanche current is generated.

A Geiger mode and a linear mode are the modes for operating an APD when a reverse bias voltage is supplied thereto. In the Geiger mode, the APD is operated in a state where a potential difference between the anode and the cathode is greater than a breakdown voltage. In the linear mode, the APD is operated in a state where a potential difference between the anode and the cathode is close to, or equal to or less than, the breakdown voltage.

An APD operated in the Geiger mode is referred to as a single-photon avalanche diode (SPAD). For example, −30 V is supplied as the voltage VL (first voltage), and 1 V is supplied as the voltage VH (second voltage). The APD 201 can be operated in either the linear mode or the Geiger mode.

A quench element 202 is connected to a power source for supplying the voltage VH and the APD 201. When signal multiplication caused by avalanche multiplication occurs, the quench element 202 functions as a load circuit (quench circuit) to suppress avalanche multiplication by suppressing the voltage supplied to the APD 201 (i.e., quench operation). Further, the quench element 202 functions to bring back the voltage supplied to the APD 201 to the voltage VH by applying an electric current corresponding to the voltage dropped by the quench operation (i.e., recharge operation).

The signal processing unit 103 includes a waveform shaping unit 210, a counter circuit 211, and a selection circuit 212. In this specification, the signal processing unit 103 may include any one of the waveform shaping unit 210, the counter circuit 211, and the selection circuit 212.

The waveform shaping unit 210 shapes a potential change of the cathode of the APD 201 acquired at the time of photon detection into a pulse signal and outputs the pulse signal. For example, an inverter circuit is used as the waveform shaping unit 210. In the example illustrated in FIG. 4, one inverter is used as the waveform shaping unit 210. However, a circuit including a plurality of inverters connected in series or another circuit having a waveform shaping effect can also be used.

The counter circuit 211 counts a pulse signal output from the waveform shaping unit 210 and retains a count value. When a control pulse pRES is supplied thereto via a drive line 213, a signal retained by the counter circuit 211 is reset.

A control pulse pSEL is supplied to the selection circuit 212 from the vertical scanning circuit 110 in FIG. 3 via a drive line 214 in FIG. 4 (not illustrated in FIG. 3), so that the electrical connection between the counter circuit 211 and the signal line 113 is switched on and off. The selection circuit 212 includes, for example, a buffer circuit for outputting a signal.

The electrical connection can be switched by arranging a switch, such as a transistor, at a position between the quench element 202 and the APD 201 or at a position between the photoelectric conversion element 102 and the signal processing unit 103. Similarly, the voltage VH or VL supplied to the photoelectric conversion element 102 can also be switched electrically by using a switch, such as a transistor.

In the present exemplary embodiment, a configuration using the counter circuit 211 is described. However, the photoelectric conversion device 100 may acquire a pulse detection timing by using a time-to-digital converter (TDC) and a memory instead of using the counter circuit 211. At this time, a generation timing of the pulse signal output from the waveform shaping unit 210 is converted into a digital signal by the TDC. In order to measure a timing of the pulse signal, a control pulse pREF (reference signal) is supplied to the TDC from the vertical scanning circuit 110 in FIG. 3 via a drive line. The TDC takes an input timing of a signal output from each of the pixels 101 via the waveform shaping unit 210 as a relative time to acquire a signal of that time as a digital signal by using the control pulse pREF as a reference.

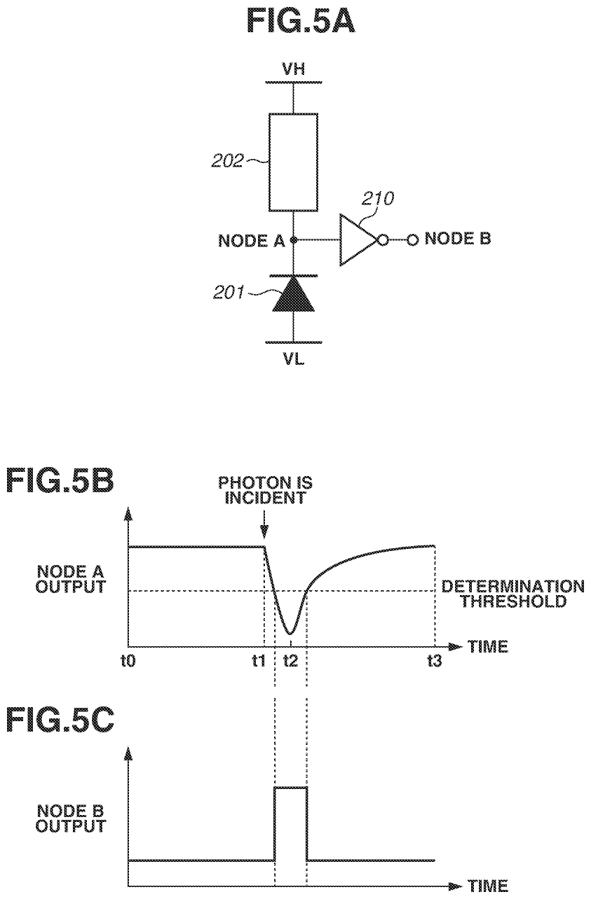

FIGS. 5A to 5C are diagrams schematically illustrating a relationship between the operation of the APD 201 and an output signal.

FIG. 5A is a diagram of a portion including the APD 201, the quench element 202, and the waveform shaping unit 210, extracted from the diagram in FIG. 4. Herein, an input side and an output side of the waveform shaping unit 210 are referred to as a node A and a node B, respectively. A change of the waveform of the node A in FIG. 5A is illustrated in FIG. 5B, and a change of the waveform of the node B in FIG. 5A is illustrated in FIG. 5C.

In a period between time t0 to time t1, a potential difference between the voltage VH and the voltage VL is applied to the APD 201 in FIG. 5A. When photons are incident on the APD 201 at time t1, avalanche multiplication occurs in the APD 201, an avalanche multiplication current flows in the quench element 202, and a voltage of the node A drops. When the amount of voltage drop becomes greater and the potential difference applied to the APD 201 becomes smaller, the avalanche multiplication occurring in the APD 201 stops at time t2, so that a voltage level of the node A does not become lower than a certain level. After that, in a period between time t2 and time t3, an electric current for compensating the amount of voltage drop flows into the node A from the voltage VL, so that the electric potential of the node A is settled at an original potential level. At this time, an output waveform exceeding a certain threshold at the node A is shaped by the waveform shaping unit 210 and output as a signal from the node B.

The arrangement of the signal line 113, the read-out circuit 112, and the output circuit 114 is not limited to the arrangement illustrated in FIG. 3. For example, the signal line 113 may extend in a row direction, and the read-out circuit 112 may be arranged at a position the signal line 113 extends to.

A photoelectric conversion device according to each of the exemplary embodiments is described below.

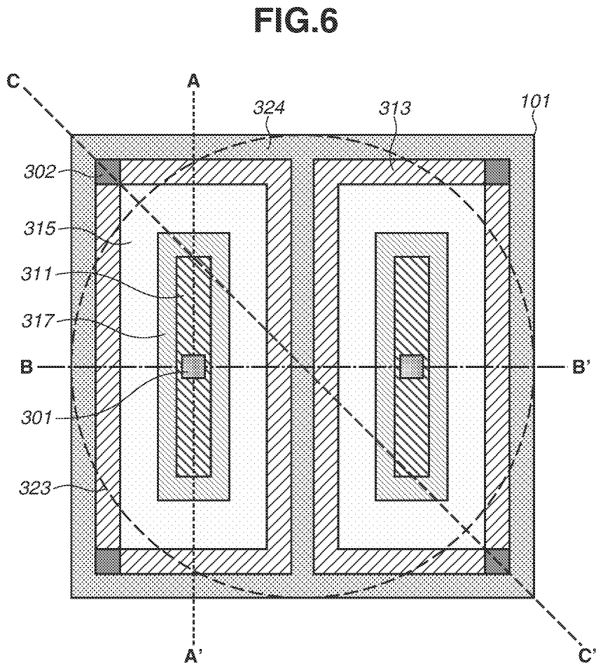

A photoelectric conversion device according to a first exemplary embodiment is described with reference to FIGS. 6 to 9.

FIG. 6 is a plan view of one pixel 101 including two APDs of a plurality of pixels 101 included in a pixel region 12. In FIG. 6, structures necessary to describe a positional relationship in a planar view are illustrated. Thus, the structures illustrated in FIG. 6 do not always exist on the same plane. In FIG. 6, arrangement of a first semiconductor region 311 is described in particular. Thus, the other structures are partially omitted.

Each of the pixels 101 includes at least one APD. In the present exemplary embodiment, the pixel 101 includes two APDs on which a microlens 323 common to the two APDs is arranged. Hereinafter, a photoelectric conversion device which includes the pixel 101 including two APDs is used as an example. However, the number of APDs included in one pixel 101 is not limited to two.

Each of the two APDs includes a first semiconductor region 311 of a first conductive type and a second semiconductor region 312 of a second conductive type (not illustrated). When a left APD in FIG. 6 is referred to as a first avalanche photodiode and a right APD in FIG. 6 is referred to as a second avalanche photodiode, the first semiconductor region 311 of the first avalanche photodiode has a length in a long side direction and a length in a short side direction. In other words, the first semiconductor region 311 of the first avalanche photodiode has a length in a first direction and a length in a second direction orthogonal to the first direction, and the length in the first direction is longer than the length in the second direction.

Each of the APDs included in the pixel 101 has one or more cathode electrodes 301 and anode electrodes 302. A cathode electrode 301 supplies a first voltage (cathode voltage) to the first semiconductor region 311 via a first contact. A first isolation portion 324A is arranged in a region between the pixels 101, and a second isolation portion 324B is arranged in a region between the APDs. A third semiconductor region 313 of the second conductive type is arranged in a region adjacent to an isolation portion 324, which includes the first isolation portion 324A and the second isolation portion 324B. The third semiconductor region 313 and an anode electrode 302 are electrically connected to each other via a second contact, and a second voltage (anode voltage) is supplied to the third semiconductor region 313 from the anode electrode 302.

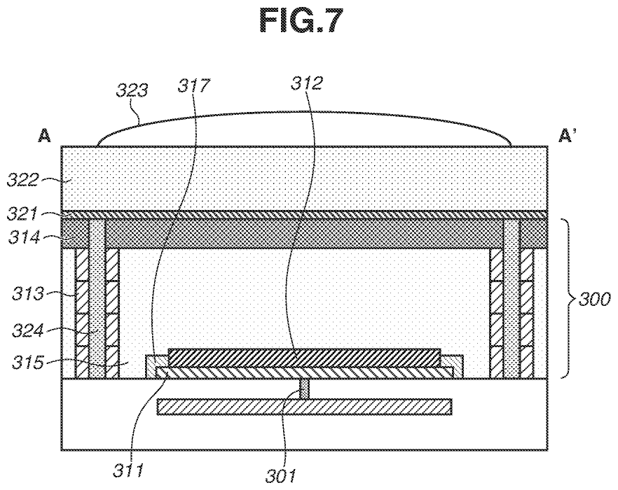

Hereinafter, details of each semiconductor region arranged in the semiconductor layer 300 is described with reference to FIGS. 7 to 9.

FIG. 7 is a cross-sectional diagram taken along a line A-A′ in FIG. 6. In FIG. 7, in addition to the semiconductor layer 300, a pinning film 321, a planarization layer 322, and a microlens 323 which are formed on a back face side of the substrate, and the cathode electrode 301 connected to the semiconductor layer 300 and part of wiring thereof which are formed on a front face side of the substrate are illustrated.

As illustrated in FIG. 7, a seventh semiconductor region 317 of the first conductive type is arranged in a periphery of the first semiconductor region 311, and the second semiconductor region 312 of the second conductive type is arranged to be adjacent to the first semiconductor region 311 in a depth direction thereof. Further, a fifth semiconductor region 315 is arranged on a back face side of the second semiconductor region 312.

The first semiconductor region 311 and the second semiconductor region 312 form a P-N junction. Avalanche multiplication occurs when a predetermined reverse voltage is applied to the first semiconductor region 311 and the second semiconductor region 312. Further, the fifth semiconductor region 315 (e.g., an epitaxial layer of the first or the second conductive type), whose second conductive type impurity concentration is lower than that of the second semiconductor region 312, is arranged in a region closer to the back face than the second semiconductor region 312 of the semiconductor layer 300. Thus, by applying a reverse bias to the P-N junction, a depletion layer spreads to the back face side of the semiconductor layer 300.

The seventh semiconductor region 317 is arranged so that at least part of the seventh semiconductor region 317 is in contact with an edge portion of the first semiconductor region 311. With this arrangement, occurrence of an edge breakdown, i.e., a breakdown occurring in the edge portion at a lower voltage, caused by an intense electric field formed at the edge portion of the first semiconductor region 311, can be suppressed.

A large number of silicon dangling bonds exist in a vicinity of an interface between the isolation portion 324 and the semiconductor layer 300, and a dark current is likely to be generated via such a defect level. In order to suppress generation of the dark current, the third semiconductor region 313 of the second conductive type is arranged to be in contact with the isolation portion 324. For a similar reason, a fourth semiconductor region 314 of the second conductive type is arranged on the back face side of the semiconductor layer 300. Further, holes are induced on the side of the semiconductor layer 300 by forming the pinning film 321 on an interface on the back face side of the semiconductor layer 300, and generation of the dark current is suppressed thereby.

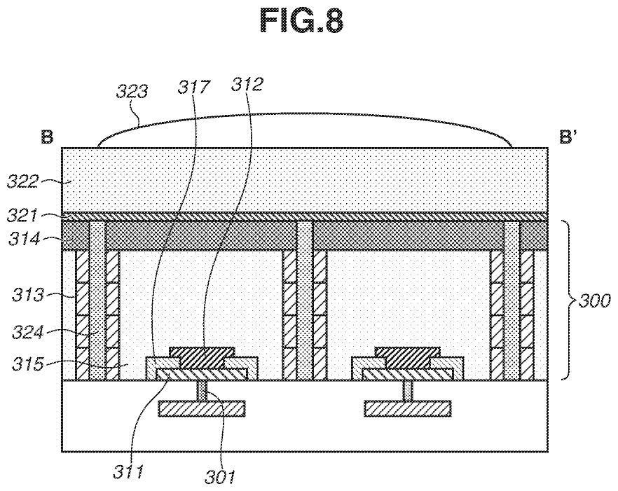

FIG. 8 is a cross-sectional diagram taken along a line B-B′ in FIG. 6. In the present exemplary embodiment, the two APDs share the one microlens 323 to constitute the one pixel 101.

As described above, by making the plurality of APDs share the one microlens 323, a light flux passing through a region with an objective lens is captured by these APDs. Thus, an amount and a direction of defocus can be detected from an output difference of the APDs under the microlens 323. Accordingly, it is possible to implement an image-plane phase difference autofocus function capable of supporting both image-capturing and phase-difference detection.

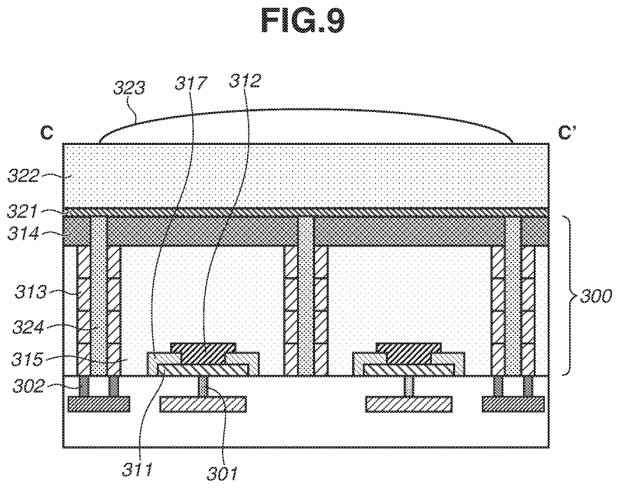

FIG. 9 is a cross-sectional diagram taken along a line C-C′ in FIG. 6. The cathode electrode 301 and the anode electrode 302 are arranged on the front face side of the semiconductor layer 300. The cathode electrode 301 is electrically connected to the first semiconductor region 311 via the first contact, and the anode electrode 302 is electrically connected to the third semiconductor region 313 via the second contact.

In FIG. 9, the anode electrodes 302 are arranged at four corners of two APDs arranged 1×2. However, the anode electrodes 302 may be arranged at four corners of one APD, or may be arranged at four corners of APDs of a greater number. For example, the anode electrodes 302 may be arranged at four corners of every four pixels each of which includes two APDs arranged 1×2. Further, part of the isolation portion 324 may separately be formed with a space therebetween because the plurality of APDs has a common anode potential. In other words, in a planar view, part of the semiconductor layer 300 may be formed to be connected to the adjacent pixel.

Herein, an issue that occurs in the APD having a long side and a short side and sharing a microlens 323, and an effect of this structure are described.

Photons incident on the pixel 101 are photoelectrically converted, and electric charges corresponding to the photons move within the semiconductor layer 300 according to an electric field. As for the APD, the electric charges are guided to and multiplied in an avalanche multiplication region in the pixel 101, thereby causing the photons to be detected. In this regard, mobility of the electric charges moving to the avalanche multiplication region vary depending on the structure of the semiconductor layer 300. The mobility of the electric charges moving in the semiconductor layer 300 has an effect on detection sensitivity of signal electric charges.

A configuration is known in which a pixel which includes two photodiodes (PDs) sharing one microlens 323 is employed for the purpose of image-plane phase difference autofocus. In the configuration, these PDs are rectangular in shape. In a case where a PD is used as an APD and the APD is square in shape, an electric field which guides the electric charges to the avalanche multiplication region can be formed by arranging the cathode electrode 301 and the first semiconductor region 311 in a central portion of the APD. On the other hand, in a case where a rectangular-shaped APD is used, there is a possibility that electric charges that are photoelectrically converted at an end portion in the long side direction of the APD away from the cathode electrode 301 cannot be guided to the avalanche multiplication region when the cathode electrode 301 and the first semiconductor region 311 are arranged in the central portion of the APD. In such a case, non-multiplied generated electric charges can be a cause of sensitivity degradation. Furthermore, an increase in variations in time necessary for the generated electric charges to reach the avalanche multiplication region can have an effect on timing jitter.

As illustrated in FIG. 6, in the present exemplary embodiment, the first semiconductor region 311 is arranged so as to extend in the long side direction of the APD. The sensitivity and timing jitter are affected by electric charges generated at the edge portion in the long side direction of the rectangular APD. Thus, it is necessary to appropriately guide the electric charges generated in that region to the avalanche multiplication region. As illustrated in FIG. 6, the first semiconductor region 311 is arranged so as to extend to a vicinity of the edge portion in the long side direction of the APD. With this configuration, an electric field can easily be formed up to a region at the edge portion of the APD having the lengths in the long side direction and the short side direction, so that it is possible to suppress degradation of the sensitivity and occurrence of the timing jitter.

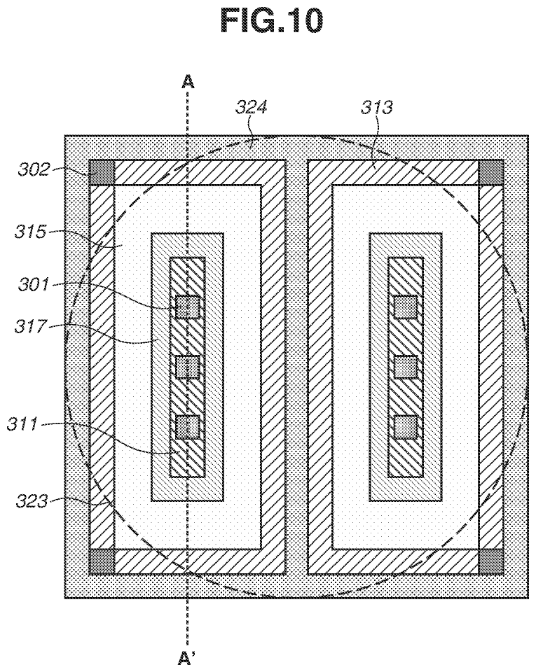

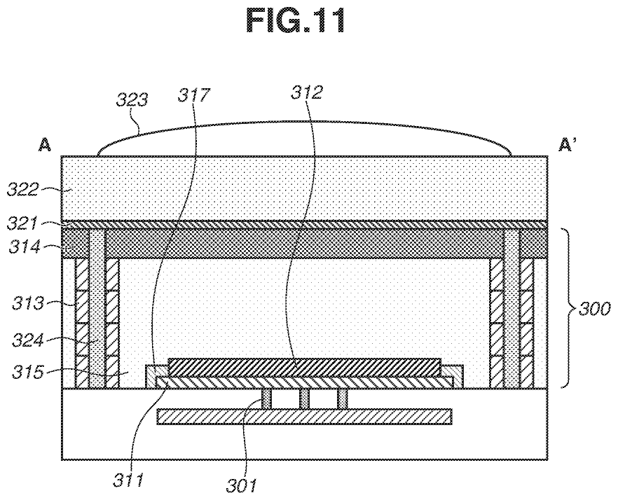

A second exemplary embodiment is described with reference to FIGS. 10 and 11. The present exemplary embodiment is different from the first exemplary embodiment with respect to the arrangement of the cathode electrode 301. Descriptions common to the first exemplary embodiment are omitted.

FIG. 10 is a plan view of one pixel arranged in a photoelectric conversion device according to the present exemplary embodiment, and FIG. 11 is a cross-sectional diagram taken along a line A-A′ in FIG. 10. As illustrated in FIGS. 10 and 11, cathode electrodes 301 are arranged in respective APDs included in the pixel 101. Each of the cathode electrodes 301 is located in a region overlapping with the first semiconductor region 311 and electrically connected to the first semiconductor region 311.

In the present exemplary embodiment, the cathode electrodes 301 are arranged more in the long side direction than in the short side direction of the APD. In the first exemplary embodiment, the configuration in which the first semiconductor region 311 extends in the long side direction of the APD has been described. However, in a case where one cathode electrode 301 is arranged in the central portion of the APD in the configuration in which the first semiconductor region 311 extends in the long side direction thereof, there is an issue that electric charges multiplied through the avalanche multiplication are not discharged appropriately. In the present exemplary embodiment, the first semiconductor region 311 is arranged to extend in the long side direction, and the cathode electrodes 301 are arranged more in the long side direction of the APD. In this way, electric potential can be supplied to the first semiconductor region 311 more stably.

In FIG. 10, while a plurality of cathode electrodes 301 is connected to the first semiconductor region 311, a cathode contact may have a shape longer in the long side direction.

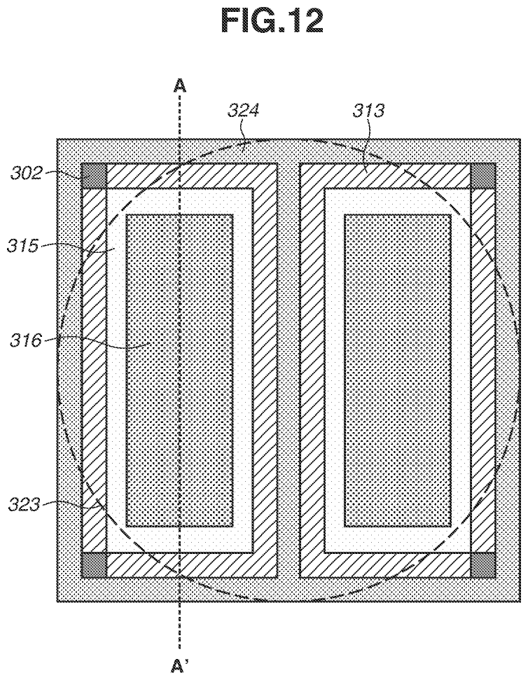

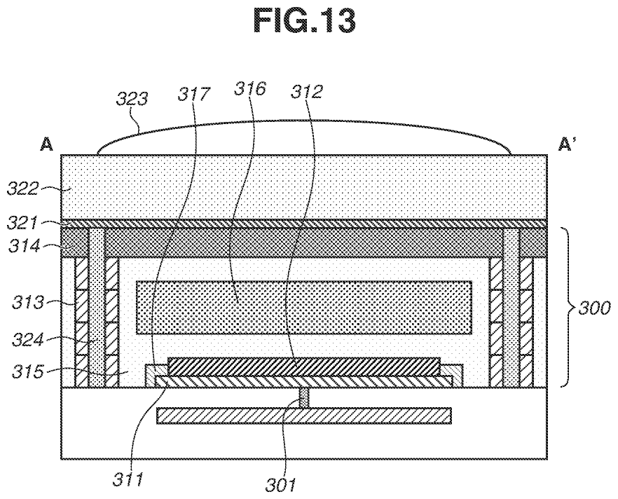

A third exemplary embodiment is described with reference to FIGS. 12 and 13. The present exemplary embodiment is different from the first and the second exemplary embodiments with respect to the arrangement of a sixth semiconductor region 316. Descriptions common to the first and the second exemplary embodiments are omitted.

FIG. 12 is a plan view of one pixel arranged in a photoelectric conversion device according to the present exemplary embodiment, and FIG. 13 is a cross-sectional diagram taken along a line A-A′ in FIG. 12. As illustrated in FIGS. 12 and 13, the sixth semiconductor region 316 is arranged in a region adjacent to the fifth semiconductor region 315. In other words, the sixth semiconductor region 316 is arranged at a position farther from a wiring structure than the first semiconductor region 311. The first conductive type impurity concentration of the sixth semiconductor region 316 is lower than that of the first semiconductor region 311 and higher than that of the fifth semiconductor region 315.

By forming the sixth semiconductor region 316, a potential gradient is formed in the depth direction, so that the electric charges can move to the avalanche multiplication region more easily.

In the present exemplary embodiment, the sixth semiconductor region 316 is formed so as to extend in the long side direction of the APD in a planar view. With the above-described configuration, an electric field toward the avalanche multiplication region can easily be formed even in a region at an edge portion in the long side direction of the APD, so that the electric charges can be guided to the avalanche multiplication region more efficiently.

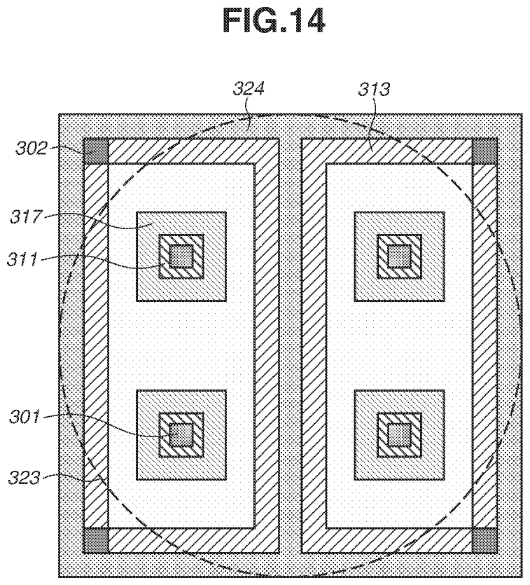

A fourth exemplary embodiment is described with reference to FIG. 14. The present exemplary embodiment is different from the first to the third exemplary embodiments with respect to the arrangement of the first semiconductor region 311. Descriptions common to the first to the third exemplary embodiments are omitted.

FIG. 14 is a plan view of one pixel arranged in a photoelectric conversion device according to the present exemplary embodiment. The present exemplary embodiment is similar to the second exemplary embodiment in that the cathode electrodes 301 are arranged more in the long side direction than in the short side direction of the APD. As illustrated in FIG. 14, the present exemplary embodiment is different from the first and the second exemplary embodiments in that first semiconductor regions 311 are arranged more in the long side direction than in the short side direction of the APD. In other words, in the photoelectric conversion device according to the present exemplary embodiment, at least two first semiconductor regions 311 of the plurality of first semiconductor regions 311 are arranged in the first direction. The number of first semiconductor regions 311 arranged in the first direction is greater than the number of first semiconductor regions 311 arranged in the second direction orthogonal to the first direction. In the example illustrated in FIG. 14, two first semiconductor regions 311 are arranged in the first direction (long side direction), and one first semiconductor region 311 is arranged in the second direction (short side direction). However, the number of first semiconductor regions 311 is not limited thereto.

For example, three first semiconductor regions 311 and two first semiconductor regions 311 may respectively be arranged in the first direction and the second direction.

At this time, similar to the arrangement described in the first exemplary embodiment, the seventh semiconductor region 317 may be arranged to cover the plurality of first semiconductor regions 311, or may be arranged to correspond to each of the plurality of first semiconductor regions 311 as illustrated in FIG. 14. Further, similar to the arrangement described in the third exemplary embodiment, the sixth semiconductor region 316 may also be arranged to extend in the long side direction of the APD.

As described above, by arranging the plurality of first semiconductor regions 311 in the long side direction, signal electric charges can easily be guided to the avalanche multiplication region from the region at the edge portion in the long side direction of the APD. In addition, the electric charges collected via the plurality of first semiconductor regions 311 are input to common wiring and a common pixel circuit.

Further, according to the configuration described in the present exemplary embodiment, an area of the avalanche multiplication region existing in the pixel can be smaller as compared to the first and the second exemplary embodiments. Therefore, it is possible to suppress dark current caused by tunnel current generated in an intense electric field region.

Further, in the second exemplary embodiment, the avalanche multiplication region has a rectangular shape or an elliptical shape. Thus, there is a case where a difference arises in the electric field at the central portion and the edge portion of the avalanche multiplication region. Therefore, for example, when the electric field is optimized with respect to the sensitivity at the central portion of the pixel, intensity of the electric field is increased at the edge portion of the pixel, so that dark current caused by tunnel current is likely to be generated. On the other hand, when the electric field is optimized with respect to the sensitivity at the edge portion of the pixel, the electric charges cannot appropriately be multiplied at the central portion of the pixel, and this could cause the sensitivity to be lowered. In the configuration described in the present exemplary embodiment, the intensity of the electric field can easily be uniform in the avalanche multiplication region as compared to the first and the second exemplary embodiments. Therefore, it is possible to suppress both degradation of the sensitivity and generation of the dark current.

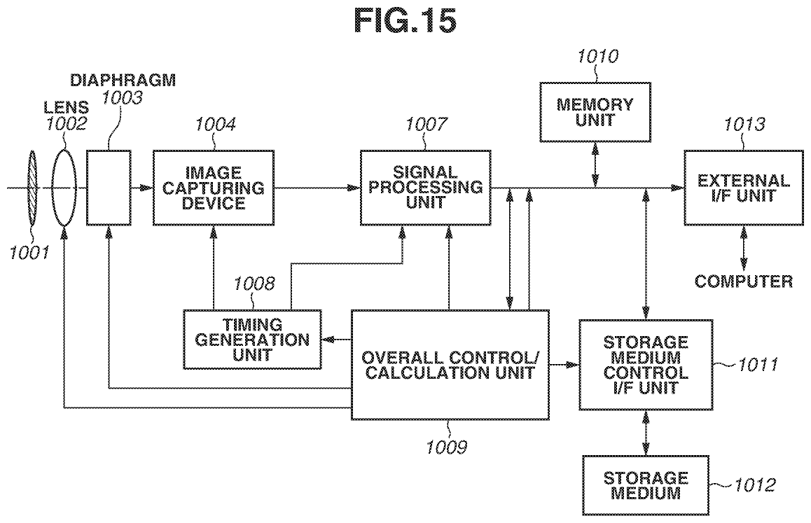

A photoelectric conversion system according to a fifth exemplary embodiment is described with reference to FIG. 15. FIG. 15 is a block diagram schematically illustrating a configuration of the photoelectric conversion system according to the present exemplary embodiment.

The photoelectric conversion device described in the first to the fourth exemplary embodiments can be applied to various photoelectric conversion systems. A digital still camera, a digital camcorder, a monitoring camera, a copying machine, a facsimile, a mobile phone, an in-vehicle camera, and an observation satellite can be given as the examples of the photoelectric conversion systems to which the above-described photoelectric conversion device can be applied. Further, a camera module including an optical system, such as a lens, and an image capturing device is also included in the photoelectric conversion systems. FIG. 15 is a block diagram of a digital still camera as one example of the above-described photoelectric conversion systems.

The photoelectric conversion system illustrated in FIG. 15 includes an image capturing device 1004 as one example of the photoelectric conversion device, and a lens 1002 which forms an optical image of an object on the image capturing device 1004. The photoelectric conversion system further includes a diaphragm 1003 capable of changing the amount of light passing through the lens 1002, and a barrier 1001 which protects the lens 1002. The lens 1002 and the diaphragm 1003 serve as an optical system which condenses light onto the image capturing device 1004. The image capturing device 1004 is a photoelectric conversion device according to any one of the above-described exemplary embodiments, and converts the optical image formed by the lens 1002 into an electric signal.

The photoelectric conversion system further includes a signal processing unit 1007 which serves as an image generation unit for generating an image by processing an output signal output from the image capturing device 1004. The signal processing unit 1007 executes processing for outputting image data after executing various types of correction and compression as necessary. The signal processing unit 1007 may be formed on a semiconductor substrate on which the image capturing device 1004 is mounted, or may be formed on a semiconductor substrate different from the semiconductor substrate on which the image capturing device 1004 is mounted.

The photoelectric conversion system further includes a memory unit 1010 for temporarily storing image data, and an external interface (I/F) unit 1013 for communicating with an external computer or the like. Furthermore, the photoelectric conversion system includes a storage medium 1012 such as a semiconductor memory for storing and reading captured image data, and a storage medium control I/F unit 1011 through which the captured image data is stored in and read from the storage medium 1012. The storage medium 1012 may be built into the photoelectric conversion system, or may be attachable to and detachable from the photoelectric conversion system.

Furthermore, the photoelectric conversion system includes an overall control/calculation unit 1009 for executing various types of calculation and control of the entire digital still camera, and a timing generation unit 1008 for outputting various timing signals to the image capturing device 1004 and the signal processing unit 1007. Herein, the timing signals may be input thereto from the outside. In this case, the photoelectric conversion system may include at least the image capturing device 1004 and the signal processing unit 1007 for processing the output signal output from the image capturing device 1004.

The image capturing device 1004 outputs a captured image signal to the signal processing unit 1007. The signal processing unit 1007 outputs image data by executing prescribed signal processing on the captured image signal output from the image capturing device 1004. The signal processing unit 1007 generates an image by using the captured image signal.

As described above, according to the present exemplary embodiment, it is possible to implement a photoelectric conversion system to which the photoelectric conversion device (i.e., image capturing device) according to any one of the above-described exemplary embodiments is applied.

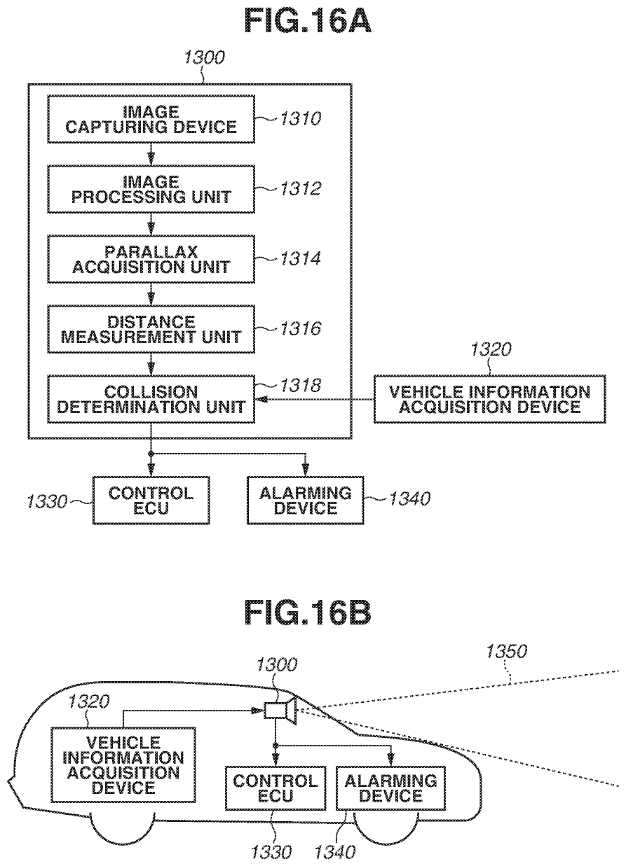

A photoelectric conversion system and a moving body according to a sixth exemplary embodiment are described with reference to FIGS. 16A and 16B. FIGS. 16A and 16B are diagrams illustrating configurations of the photoelectric conversion system and the moving body according to the present exemplary embodiment.

FIG. 16A is a diagram illustrating an example of the photoelectric conversion system related to an in-vehicle camera. A photoelectric conversion system 1300 includes an image capturing device 1310. The image capturing device 1310 is the photoelectric conversion device according to any one of the above-described exemplary embodiments. The photoelectric conversion system 1300 includes an image processing unit 1312 that executes image processing on a plurality of pieces of image data acquired by the image capturing device 1310, and a parallax acquisition unit 1314 that executes calculation of a parallax (i.e., a phase difference of parallax images) from the plurality of pieces of image data acquired by the image capturing device 1310. The photoelectric conversion system 1300 further includes a distance measurement unit 1316 that calculates a distance to a target object based on the calculated parallax, and a collision determination unit 1318 that determines whether a moving body has a possibility of collision based on the calculated distance. Herein, the parallax acquisition unit 1314 and the distance measurement unit 1316 are examples of a distance information acquisition unit which acquires distance information indicating a distance to the target object. In other words, distance information refers to information about a parallax, a defocus amount, and a distance to a target object. The collision determination unit 1318 may determine the possibility of collision by using any one of the pieces of distance information. The distance information acquisition unit may be implemented by hardware designed exclusively, or may be implemented by a software module.

Further, the distance information acquisition unit may be implemented by a field programmable gate array (FPGA) or an application specific integrated circuit (ASIC), or may be implemented by a combination of these elements. The photoelectric conversion system 1300 is connected to a vehicle information acquisition device 1320, and can acquire vehicle information such as a vehicle speed, a yaw rate, and a rudder angle. Further, the photoelectric conversion system 1300 is connected to a control electronic control unit (ECU) 1330 which serves as a control unit that outputs a control signal for generating braking force to a vehicle based on a determination result acquired by the collision determination unit 1318. The photoelectric conversion system 1300 is also connected to an alarming device 1340 which issues a warning to a driver based on a determination result acquired by the collision determination unit 1318. For example, in a case where the collision determination unit 1318 determines that the possibility of collision is high, the control ECU 1330 executes vehicle control for avoiding the collision and/or reducing damages by applying a brake, releasing a gas pedal, or suppressing an engine output. The alarming device 1340 issues a warning to a driver by making an alarm sound, displaying alarming information on a display screen of a car navigation system, or producing vibrations in a seat belt or steering wheels.

In the present exemplary embodiment, peripheral views of the vehicle, e.g., a forward view and a backward view of the vehicle, are captured by the photoelectric conversion system 1300. FIG. 16B is a diagram illustrating a photoelectric conversion system in a case where a forward view (image capturing range 1350) of the vehicle is captured. The vehicle information acquisition device 1320 issues an instruction to the photoelectric conversion system 1300 or the image capturing device 1310. With the above-described configuration, it is possible to further improve the range finding accuracy.

In the above example, control which prevents a vehicle from colliding with another vehicle has been described. However, the present exemplary embodiment is also applicable to control which allows a vehicle to be autonomously driven while following another vehicle or control which allows a vehicle to be autonomously driven without being drifted out of a traffic lane. Further, the photoelectric conversion system can be applied not only to vehicles such as an automobile but also to moving bodies (moving apparatuses) such as a ship, an airplane, and an industrial robot. Furthermore, the photoelectric conversion system can widely be applied to devices such as intelligent transportation systems (ITS) which employ object recognition functions, in addition to the moving bodies.

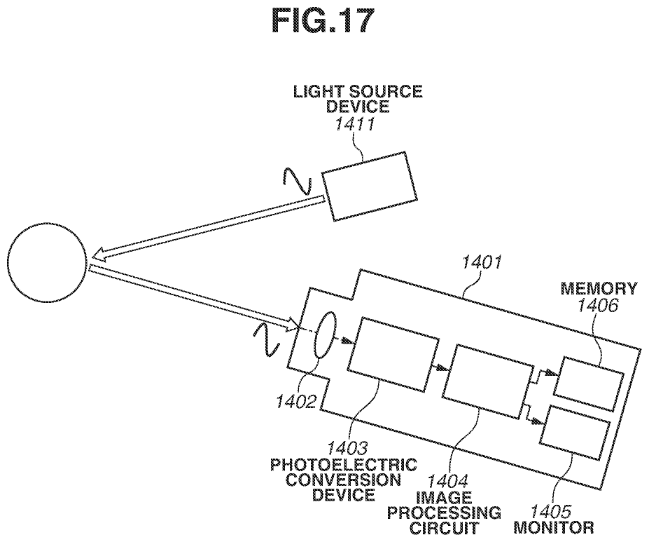

A photoelectric conversion system according to a seventh exemplary embodiment is described with reference to FIG. 17. FIG. 17 is a block diagram illustrating an example of a configuration of a range image sensor as a photoelectric conversion system according to the present exemplary embodiment.

As illustrated in FIG. 17, a range image sensor 1401 includes an optical system 1402, a photoelectric conversion device 1403, an image processing circuit 1404, a monitor 1405, and a memory 1406. The range image sensor 1401 can acquire a range image based on a distance to an object by receiving light (modulated light or pulsed light) emitted from a light source device 1411 to an object and reflected on a surface of the object.

The optical system 1402 includes one lens or a plurality of lenses, guides image light (incident light) from the object to the photoelectric conversion device 1403, and forms an image on a light receiving face (sensor portion) of the photoelectric conversion device 1403.

The photoelectric conversion device according to any one of the above-described exemplary embodiments is applied as the photoelectric conversion device 1403, and a distance signal indicating a distance acquired from a light receiving signal output from the photoelectric conversion device 1403 is supplied to the image processing circuit 1404.

The image processing circuit 1404 executes image processing to create a range image based on the distance signal supplied from the photoelectric conversion device 1403. Then, the range image (image data) acquired by the image processing is supplied to and displayed on the monitor 1405, or supplied to and stored (recorded) in the memory 1406.

Applying the above-described photoelectric conversion device results in improvement in properties of pixels in the range image sensor 1401 configured as the above. Therefore, for example, the range image sensor 1401 can acquire a range image with higher accuracy.

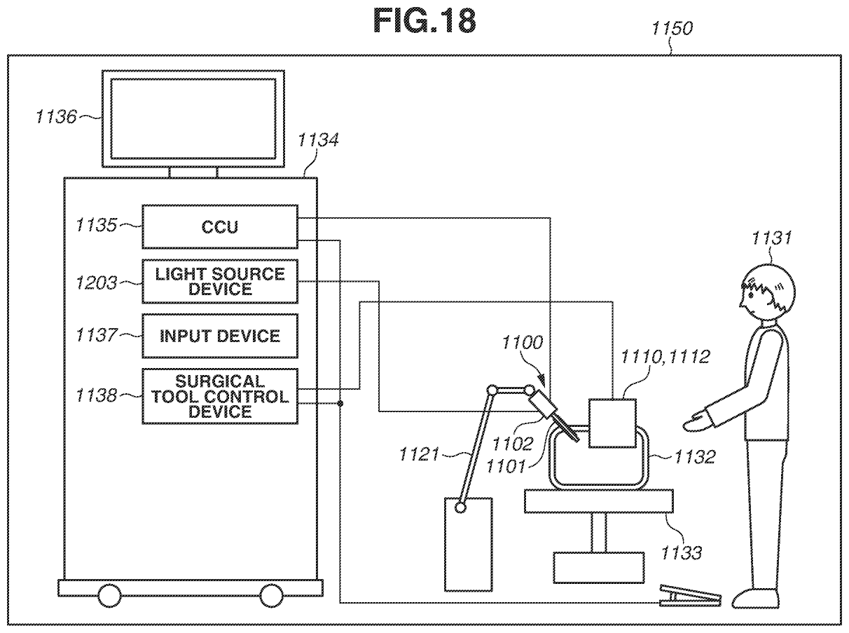

A photoelectric conversion system according to an eighth exemplary embodiment is described with reference to FIG. 18. FIG. 18 is a diagram schematically illustrating an example of a configuration of an endoscopic operation system as the photoelectric conversion system according to the present exemplary embodiment.

In FIG. 18, an operator (doctor) 1131 performs a surgical operation on a patient 1132 lying on a patient bed 1133 by using an endoscopic operation system 1150. As illustrated in FIG. 18, the endoscopic operation system 1150 includes an endoscope 1100, a surgical tool 1110, and a cart 1134 on which various devices used for the endoscopic operation are mounted.

The endoscope 1100 includes a lens barrel 1101, whose leading end region having a prescribed length is inserted into a body cavity of the patient 1132, and a camera head 1102 connected to a base end section of the lens barrel 1101. In the example illustrated in FIG. 18, the endoscope 1100 is illustrated as what is called a rigid endoscope having a rigid lens barrel 1101. However, the endoscope 1100 can be what is called a flexible endoscope having a flexible lens barrel.

At a leading end of the lens barrel 1101, there is an opening portion on which an objective lens is mounted. A light source device 1203 is connected to the endoscope 1100, so that light generated by the light source device 1203 is guided to the leading end of the lens barrel 1101 by a light guide arranged to extend through an inner portion of the lens barrel 1101 and emitted to an observation target inside the body cavity of the patient 1132 via the objective lens. The endoscope 1100 can be a forward viewing endoscope, an oblique viewing endoscope, or a side viewing endoscope.

An optical system and a photoelectric conversion device are arranged inside the camera head 1102, and reflected light (observation light) from the observation target is condensed onto the photoelectric conversion device by the optical system. The photoelectric conversion device executes photoelectric conversion on the observation light and generates an electric signal corresponding to the observation light, i.e., an image signal corresponding to an observation image. The photoelectric conversion device according to any one of the above-described exemplary embodiments can be used as the photoelectric conversion device. The image signal is transmitted to a camera control unit (CCU) 1135 in a form of RAW data.

The CCU 1135 includes a central processing unit (CPU) and a graphics processing unit (GPU), and generally controls operations of the endoscope 1100 and a display device 1136. Further, the CCU 1135 receives an image signal from the camera head 1102, and executes various types of image processing such as development processing (de-mosaic processing) on the image signal to display an image based on the image signal.

The display device 1136 is controlled by the CCU 1135 and displays an image based on the image signal on which the image processing is executed by the CCU 1135.

The light source device 1203 includes a light source such as a light emitting diode (LED), and supplies irradiation light to the endoscope 1100 when an operative field image is to be captured.

An input device 1137 serves as an input interface for the endoscopic operation system 1150. A user can input various types of information and instructions to the endoscopic operation system 1150 via the input device 1137.

A surgical tool control device 1138 executes driving control of an energy surgical tool 1112 used for cauterizing and incising body tissues or sealing a blood vessel.

The light source device 1203 supplies irradiation light to the endoscope 1100 when an operative field image is to be captured. For example, the light source device 1203 can be a white light source which includes an LED, a laser light source, or a combination of these elements. In a case where the white light source includes a combination of red, green, and blue (RGB) laser light sources, output intensities and output timings of the laser light sources of respective colors (wavelengths) can be controlled with high accuracy. Thus, the light source device 1203 can make an adjustment of white balance of the captured image. In this case, the observation target is irradiated with laser light beams respectively emitted from the RGB laser light sources in a time division manner, and driving of image sensors mounted on the camera head 1102 is controlled in synchronization with the irradiation timing. In this way, images corresponding to respective RGB laser beams can be captured in a time division manner. By the above-described method, color images can be acquired even if color filters are not arranged on the image sensors.

Further, the light source device 1203 may be controlled to be driven to change the intensity of output light at every prescribed time. The endoscopic operation system 1150 acquires images in a time division manner by controlling driving of the image sensors mounted on the camera head 1102 in synchronization with the timing of changing the light intensity, and can generate a high dynamic range image without an overexposed or underexposed part by combining the acquired images.

The light source device 1203 may be configured to supply light of a prescribed wavelength band for supporting special light observation. For example, the special light observation is executed by making use of wavelength dependence on light absorption characteristics of the body tissues. Specifically, an image of specific tissues, such as blood vessels on a superficial portion of a mucous membrane, is captured with high contrast by irradiating the tissues with light having a wavelength band narrower than a wavelength band of irradiation light (i.e., white light) used for normal observation.

Alternatively, as the special light observation, fluorescence observation for acquiring an image of fluorescence generated by irradiating the body tissues with excitation light may be executed. In the fluorescence observation, fluorescence from the body tissues can be observed by irradiating the body tissues with excitation light. Further, a fluorescent image can be acquired by locally injecting a reagent such as indocyanine green (ICG) into the body tissues and irradiating the body tissues with excitation light corresponding to the fluorescence wavelength of the reagent. The light source device 1203 can supply narrow-band light and/or excitation light supporting the special light observation described above.

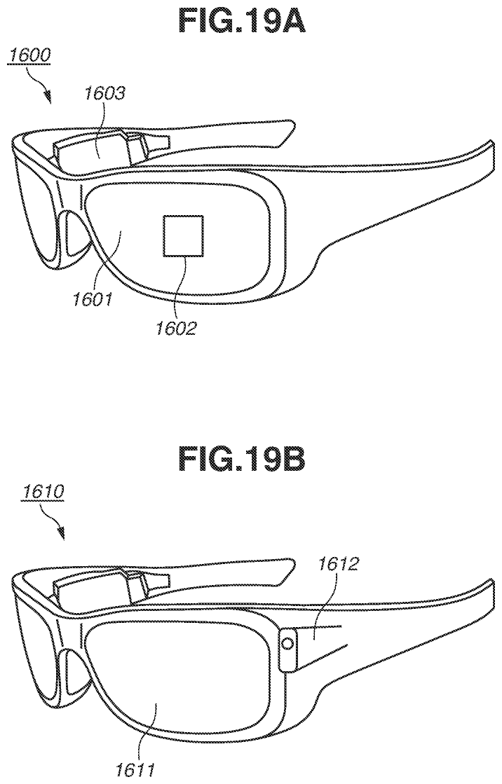

A photoelectric conversion system according to a ninth exemplary embodiment is described with reference to FIGS. 19A and 19B. FIG. 19A is a diagram illustrating a pair of eyeglasses 1600 (pair of smart-glasses) as the photoelectric conversion system according to the present exemplary embodiment. The pair of eyeglasses 1600 includes a photoelectric conversion device 1602. The photoelectric conversion device 1602 is the photoelectric conversion device according to any one of the above-described exemplary embodiments. Further, a display device including a light emitting device such as an organic light emitting diode (OLED) or an LED may be mounted on a back face side of each lens 1601. One or more photoelectric conversion devices 1602 may be mounted thereon. Further, a plurality of types of photoelectric conversion devices 1602 may be used in combination. A mounting position of the photoelectric conversion device 1602 is not limited to the position indicated in FIG. 19A.

The pair of eyeglasses 1600 further includes a control device 1603. The control device 1603 functions as a power source for supplying power to the photoelectric conversion device 1602 and above-described display devices. The control device 1603 further controls operations of the photoelectric conversion device 1602 and the display devices. An optical system which condenses light onto the photoelectric conversion device 1602 is formed on the lens 1601.

FIG. 19B is a diagram illustrating a pair of eyeglasses 1610 (pair of smart-glasses) according to one application example. The pair of eyeglasses 1610 includes a control device 1612, and a photoelectric conversion device corresponding to the photoelectric conversion device 1602 and a display device are mounted on the control device 1612. An optical system for projecting light emitted from the photoelectric conversion device and the display device included in the control device 1612 is formed on each lens 1611, so that an image is projected thereon. The control device 1612 functions as a power source for supplying power to the photoelectric conversion device and the display device, and also controls operations of the photoelectric conversion device and the display device. The control device 1612 may include a line-of-sight detection unit that detects a line-of-sight of the user. Infrared light may be used to detect the line-of-sight. An infrared light emitting unit emits infrared light to the eyeball of the user who is gazing at a displayed image. An image capturing unit including a light receiving element detects the emitted infrared light reflected on the eyeball, so that a captured image of the eyeball is acquired. Degradation of image quality can be prevented by providing a reduction unit for reducing light emitted to the display device from the infrared light emitting unit in a planar view.

The control device 1612 detects a line-of-sight of the user gazing at the displayed image from the captured image of the eyeball acquired by image capturing using infrared light. A known method can be employed for line-of-sight detection using the captured image of the eyeball. For example, it is possible to employ a line-of-sight detection method based on a Purkinje image acquired from irradiation light reflected on the cornea.

More specifically, line-of-sight detection processing is executed based on a pupil-corneal reflection method. By employing the pupil-corneal reflection method, a line-of-sight vector which represents the orientation (rotation angle) of the eyeball is calculated based on a pupil image and the Purkinje image included in the captured image of the eyeball, and the user's line-of-sight is detected from the calculated line-of-sight vector.

The display device according to the present exemplary embodiment may include a photoelectric conversion device including a light emitting element, and may control an image displayed on the display device based on the user's line-of-sight information received from the photoelectric conversion device.

Specifically, based on the line-of-sight information, a first field-of-view region and a second field-of-view region of the display device are determined. The first field-of-view region is a region the user is gazing at, and the second field-of-view region is a region different from the first field-of-view region. The first and the second field-of-view regions may be determined by the control device of the display device. Alternatively, the display device may receive the first and the second field-of-view regions determined by an external control device. A display resolution of the first field-of-view region may be controlled to be higher than a display resolution of the second field-of-view region in a display region of the display device. In other words, the resolution of the second field-of-view region may be lower than the resolution of the first field-of-view region.

Further, the display region has a first display region and a second display region different from the first display region, and a region given a high priority may be determined from the first and the second display regions based on the line-of-sight information. The first and the second display regions may be determined by the control device of the display device. Alternatively, the display device may receive the first and the second display regions determined by an external control device. A resolution of the region given a high priority may be controlled to be higher than a resolution of a region different from the region given a high priority. In other words, a resolution of the region given a relatively low priority may be lower.

In addition, artificial intelligence (AI) may be used to determine the first field-of-view region and the region given a high priority. The AI may be a model which is designed to estimate an angle of a line-of-sight and a distance to an object to which the line-of-sight is directed from an image of the eyeball by using the image of the eyeball and an actual line-of-sight direction of the eyeball captured in that image as training data. An AI program may be included in the display device, the photoelectric conversion device, or an external device. In a case where the AI program is included in the external device, information is transmitted to the display device through communication.

The photoelectric conversion system according to the present exemplary embodiment can favorably be applied to a pair of smart-glasses further including a photoelectric conversion device that captures an outside view in a case where display control is executed based on a line-of-sight detection. The pair of smart-glasses can display information about the captured outside view in real time.

The present disclosure is not limited to the above-described exemplary embodiments, and various modifications are possible.

For example, an exemplary embodiment in which part of the configuration according to any one of the above-described exemplary embodiments is added to the configuration according to another exemplary embodiment or replaced with part of the configuration according to another exemplary embodiment is also included in the exemplary embodiments of the present disclosure.

Further, the photoelectric conversion systems described above in the fifth and the sixth exemplary embodiments are merely the examples of a photoelectric conversion system to which the photoelectric conversion device can be applied, and the photoelectric conversion system to which the photoelectric conversion device according to the present disclosure is applicable is not limited to those illustrated in FIG. 15 to FIG. 19B. The same can be said for the ToF system described in the seventh exemplary embodiment, the endoscopic operation system described in the eighth exemplary embodiment, and the pair of smart-glasses described in the ninth exemplary embodiment.

In addition, the above-described exemplary embodiments are merely the examples embodying the present disclosure and shall not be construed as limiting the technical range of the present disclosure. In other words, the present disclosure can be realized in diverse ways without departing from the technical spirit or main features of the present disclosure.

According to the present disclosure, it is possible to improve the sensitivity of the photoelectric conversion device.

While the disclosure has been described with reference to exemplary embodiments, it is to be understood that the disclosure is not limited to the disclosed exemplary embodiments. The scope of the following claims is to be accorded the broadest interpretation so as to encompass all such modifications and equivalent structures and functions.

This application claims the benefit of Japanese Patent Application No. 2023-067177, filed Apr. 17, 2023, which is hereby incorporated by reference herein in its entirety.

What is claimed is:

1. A device comprising:
a plurality of photodiodes each including a first region of a first conductivity type and a second region of a second conductivity type;
a microlens provided to be shared by at least a first photodiode and a second photodiode of the plurality of photodiodes; and
a first contact configured to supply a first voltage to the first region,
wherein a length in a first direction of the first region of the first photodiode is different from a length in a second direction of the first region of the first photodiode orthogonal to the first direction.

2. The device according to claim 1, wherein the length in the first direction is longer than the length in the second direction.

3. The device according to claim 2,
wherein a plurality of first contacts is arranged on the first region, and
wherein at least two first contacts of the plurality of first contacts are arranged in the first direction.

4. The device according to claim 2, further comprising:
a wiring structure including wiring connected to the first contact; and
a third region arranged at a position farther from the wiring structure than the first region, an impurity concentration of the first conductivity type of the third region being lower than an impurity concentration of the first conductivity type of the first region,
wherein the third region has a shape extending in the first direction.

5. The device according to claim 2, wherein the first contact has a shape extending in the first direction.

6. The device according to claim 1, further comprising a second contact configured to supply a second voltage to the second region,
wherein a difference between potentials of the first voltage and the second voltage is greater than a breakdown voltage of the first photodiode.

7. The device according to claim 6,
wherein a first portion is arranged at a position between the first photodiode and another photodiode which does not share the microlens with the first photodiode, and
wherein the second contact is arranged on the first portion.

8. The device according to claim 7,
wherein a second portion is arranged at a position between the first photodiode and the second photodiode, and
wherein the second contact is not arranged on the second portion.

9. A device comprising:
a plurality of photodiodes each including a plurality of first regions of a first conductive type and a plurality of second regions of a second conductive type;
a microlens provided to be shared by at least a first photodiode and a second photodiode of the plurality of photodiodes; and
a plurality of first contacts configured to supply a first voltage to each of the plurality of first regions of the first photodiode,
wherein, at least two first regions of the plurality of first regions of the first photodiode are arranged in a first direction, and
wherein a number of first regions arranged in the first direction is greater than a number of first regions arranged in a second direction orthogonal to the first direction.

10. The device according to claim 9, further comprising:
a wiring structure including wiring connected to the first contact; and
a third region arranged at a position farther from the wiring structure than the first region, an impurity concentration of the first conductivity type of the third region being lower than an impurity concentration of the first conductivity type of the first region,
wherein the third region has a shape extending in the first direction.

11. The device according to claim 9,
wherein a second voltage is supplied to the second region via a second contact, and
wherein a difference between potentials of the first voltage and the second voltage is greater than a breakdown voltage of the first photodiode.

12. The device according to claim 11,
wherein a first portion is arranged at a position between the first photodiode and another photodiode which does not share the microlens with the first photodiode, and
wherein the second contact is arranged on the first portion.

13. The device according to claim 12,
wherein a second portion is arranged at a position between the first photodiode and the second photodiode, and
wherein the second contact is not arranged on the second portion.

14. A system comprising:
the device according to claim 1; and
a signal processing unit configured to generate an image by using a signal output from the device.

15. A moving body including the device according to claim 1, the moving body comprising a control unit configured to control movement of the moving body by using a signal output from the device.
